(19) United States
(12) Patent Application Publication
(10) Pub. No.: US 2024/0105827 A1
(43) Pub. Date: Mar. 28, 2024

(54) SEMICONDUCTOR STRUCTURE

(71) Applicant: GaNrich Semiconductor Corporation, Hsinchu City (TW)

(72) Inventors: Chih-Hao CHEN, Hsinchu City (TW); Yi-Ru SHEN, Hsinchu City (TW); Yi-Chao LIN, Hsinchu City (TW)

(21) Appl. No.: 18/226,181

(22) Filed: Jul. 25, 2023

(30) Foreign Application Priority Data
Sep. 23, 2022 (TW) 111136097

(51) Int. Cl. H01L 29/778; H01L 29/20

(52) U.S. Cl. CPC H01L 29/7786; H01L 29/2003

(57) ABSTRACT

A semiconductor structure includes a first channel layer and a first barrier layer on the first channel layer. The first channel layer has a first potential well adjacent to the interface between the first channel layer and the first barrier layer. The semiconductor structure further includes a second channel layer on the first barrier layer, a second barrier layer on the second channel layer, and an intermediate layer between the second channel layer and the second barrier layer. The second channel layer has a second potential well adjacent to the interface between the second channel layer and the intermediate layer. The intermediate layer has a greater energy gap than either the first barrier layer or the second barrier layer. The energy gap of the first barrier layer is no less than the energy gap of the second barrier layer.

### CROSS REFERENCE TO RELATED APPLICATIONS

This application claims priority of Taiwan Patent Application No. 111136097 filed on Sep. 23, 2022, the entirety of which is incorporated by reference herein.

### BACKGROUND

### Technical Field

The present disclosure relates to a semiconductor structure, and in particular to a structure with high current density.

### Description of the Related Art

In recent years, the demand for high-frequency and high-power products has been increasing. Semiconductor power devices made of gallium nitride (GaN) based material include aluminum gallium nitride/gallium nitride (AlGaN/GaN) high electron mobility transistors (HEMTs). HEMTs have high electron mobility, high switching speed, and characteristics allow them to operate in high-frequency, high-power, and high-temperature operating environments. These have been widely used in such applications as power supplies, DC/DC converters, AC/DC inverters, and other industrial applications. The fields in which high electron mobility transistors may be applied include electronic products, uninterruptible power systems (UPS), automobiles, motors, and wind-power generation.

In high electron mobility transistors, in order to pursue higher current density, it is necessary to further improve the existing high electron mobility transistors.

### SUMMARY

An embodiment of the present disclosure provides a semiconductor structure, including a first channel layer, a first barrier layer, a second channel layer, a second barrier layer, and an intermediate layer. The first channel layer and the first barrier layer respectively include group III nitride semiconductor materials. The first barrier layer is on the first channel layer. The first channel layer has a first potential well adjacent to the interface between the first channel layer and the first barrier layer. The first potential well has a two-dimensional electron gas (2DEG). The second channel layer and the second barrier layer respectively include group III nitride semiconductor materials. The second channel layer is on the first barrier layer. The second barrier layer is on the second channel layer. The intermediate layer is between the second channel layer and the second barrier layer. The intermediate layer includes a group III nitride semiconductor material. The second channel layer has a second potential well adjacent to the interface between the second channel layer and the intermediate layer. The second potential well has a two-dimensional electron gas. The energy gap of the intermediate layer is greater than the energy gap of the first barrier layer and the energy gap of the second barrier layer. The energy gap of the first barrier layer is no less than the energy gap of the second barrier layer. The energy gap of the first barrier layer is lower than the energy gap of the intermediate layer. The depth of the second potential well is greater than the depth of the first potential well in an energy band diagram.

Another embodiment of the present disclosure provides a semiconductor structure, including a plurality of channel structures and a contact layer over the channel structures. The channel structures are stacked sequentially in the first direction. Each of the channel structures includes a channel layer, and a barrier layer on the channel layer. The channel layer and the barrier layer each include a group III nitride semiconductor material. The channel layer has a potential well adjacent to the interface between the channel layer and the barrier layer. The potential well has two-dimensional electron gas. The energy gap of the n^{th} barrier layer along the first direction is no greater than the energy gap of the n+1^{th} barrier layer along the first direction, wherein n is a natural number. The energy gap of the topmost barrier layer is greater than the energy gap of any other barrier layer. The depth of the n^{th} potential well along the first direction is no greater than the depth of the n+1^{th} potential well along the first direction. The depth of the topmost potential well is greater than the depth of any other potential well in an energy band diagram. The contact layer includes a group III nitride semiconductor material. The energy gap of the contact layer is not greater than the energy gap of any other barrier layer.

### BRIEF DESCRIPTION OF THE DRAWINGS

Aspects of the present disclosure are best understood from the following detailed description when read with the accompanying figures. It should be emphasized that, in accordance with the standard practice in the industry, various features are not drawn to scale. In fact, the dimensions of the various features may be arbitrarily increased or reduced for clarity of discussion.

FIG. 1 illustrates a cross-sectional view of the semiconductor structure according to the embodiment of the present disclosure;

FIG. 2 illustrates an energy band diagram of the semiconductor structure along the line A-A′ of FIG. 1 according to the embodiment of the present disclosure;

FIG. 3 illustrates a cross-sectional view of the semiconductor structure according to another embodiment of the present disclosure; and

FIG. 4 illustrates a cross-sectional view of the semiconductor structure according to the other embodiment of the present disclosure.

### DETAILED DESCRIPTION OF THE EMBODIMENTS

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during the manufacturing process, as understood by one of ordinary skill in the art. For example, the number or range of numbers encompasses a reasonable range including the number described, such as within +/−30% of the number described (e.g., within +/−10%, within +/−20%, or within +/−30% of the number described), based on known manufacturing tolerances associated with manufacturing a feature having a characteristic associated with the number.

Embodiments of the present disclosure relate to high electron mobility transistor (HEMT) elements with multiple channels, and in particular to super lattice structures with gradients of varying aluminum (Al) concentration. The semiconductor structure of the embodiments of the present disclosure may be included in integrated circuits (IC) such as microprocessors, memory elements, and/or other elements. The integrated circuits described above may also include different passive and active microelectronic components, such as thin-film resistors, other types of capacitors such as metal-insulator-metal capacitors (MIMCAP), inductors, diodes, metal-oxide-semiconductor field-effect transistors (MOSFETs), complementary metal-oxide-semiconductor (CMOS) transistors, bipolar junction transistors (BJTs), laterally diffused metal-oxide-semiconductor (LDMOS) transistors, high-power metal-oxide-semiconductor transistors, or other types of transistors.

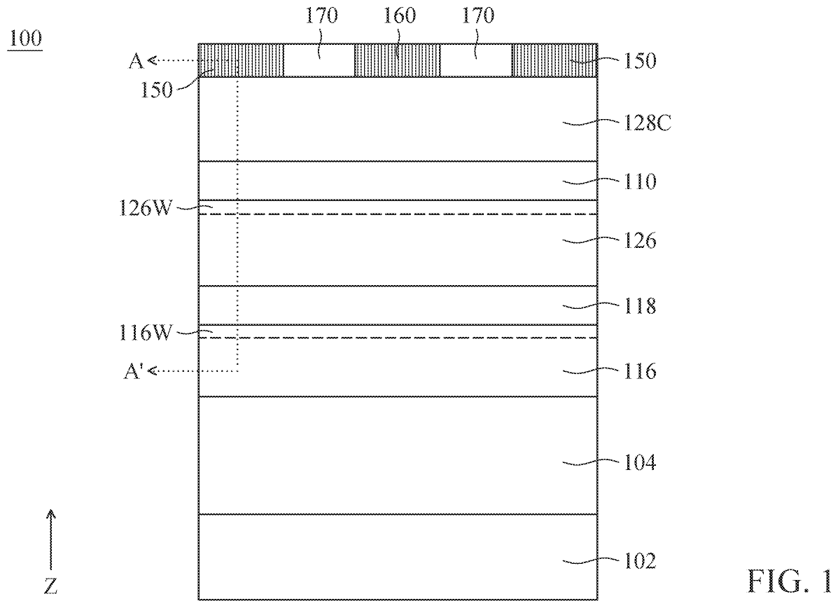

FIG. 1 illustrates a cross-sectional view of the semiconductor structure 100 according to an embodiment of the present disclosure. In one embodiment, the semiconductor structure 100 includes a substrate 102. In some embodiments, the material of the substrate 102 may include semiconductor materials or non-semiconductor materials. The semiconductor material may include silicon (Si), gallium nitride (GaN), silicon carbide (SiC), or gallium arsenide (GaAs), and the non-semiconductor material may include sapphire. In some embodiments, if it is distinguished by conductivity, the substrate 102 may be a conductive substrate or an insulating substrate. In some embodiments, the conductive substrate may include a silicon (Si) substrate, a silicon carbide (SiC) substrate, a gallium nitride (GaN) substrate, or a gallium arsenide (GaAs) substrate. In some embodiments, the insulating substrate may include a sapphire substrate, or a semiconductor-on-insulation (SOI) substrate. In one embodiment, the substrate 102 is a silicon substrate.

Continuing referring to FIG. 1, in one embodiment, the semiconductor structure 100 includes a buffer structure 104 formed on the substrate 102. Forming the buffer structure 104 on the substrate 102 may ensure the epitaxial quality of the channel layer (e.g., the channel layer 116) or the barrier layer (e.g., the barrier layer 118) formed on the substrate 102 subsequently. The buffer structure 104 may buffer the stress generated by the difference in thermal expansion coefficients between the substrate 102 and the channel layer (e.g., channel layer 116), or the buffer structure 104, or may buffer the strain generated by the mismatch in lattice constants, thereby reducing the defects of the lattice. The buffer structure 104 may be a single-layer or multi-layer structure. In some embodiments, the buffer structure 104 is a multi-layer structure, and may include, for example, a grading layer, a super lattice stack layer, or a stack layer of two or more layers of different materials. In some embodiments, the buffer structure 104 may be a combination of a nucleation layer and a transition layer, and the nucleation layer may include a monolayer or a composite layer. For example, the monolayer may include AlN, and the composite layer may include an alternate stack of AlN sublayers formed by low temperature epitaxy and AlN sublayers formed by high temperature epitaxy. In some embodiments, the buffer structure 104 may be formed by chemical vapor deposition (CVD), metal organic chemical vapor deposition (MOCVD), molecular beam epitaxy (MBE), physical vapor deposition (PVD), atomic layer deposition (ALD), or other suitable processes. In some embodiments, the material of the buffer structure 104 may include materials such as GaN, AlN, AlGaN, AlInN, AlInGaN, or the like. In other embodiments, the buffer structure 104 may be doped with other elements, for example, the buffer structure 104 may be doped with silicon (Si), carbon (C), hydrogen (H), oxygen (O), or a combination thereof, and the doping concentration of the element may be gradual or fixed along the forming direction of the buffer structure 104.

Continuing referring to FIG. 1, in one embodiment, the semiconductor structure 100 further includes a first channel layer 116 and a first barrier layer 118, wherein the first channel layer 116 is formed on the buffer structure 104, and the first barrier layer 118 is formed on the first channel layer 116. The first channel layer 116 is in direct contact with the first barrier layer 118. Since the first channel layer 116 and the first barrier layer 118 have a work function difference, the first channel layer 116 and the first barrier layer 118 may form spontaneous polarization. Further, the first channel layer 116 and the first barrier layer 118 are affected by the sum of different lattice constants interacting with each other between the first channel layer 116 and the underlying stack (e.g., buffer structure 104), thereby forming a piezoelectric polarization on the first barrier layer 118. Therefore, the first channel layer 116 has a first potential well 116W adjacent to an interface (i.e., heterojunction) between the first channel layer 116 and the first barrier layer 118, and the first potential well 116W has two-dimensional electron gas (2DEG). It should be noted that the intensity of the two-dimensional electron gas is related to the thickness of the first barrier layer 118, and the greater the thickness of the first barrier layer 118, the greater the electron concentration of the two-dimensional electron gas will be. In addition, the composition of the first barrier layer 118 may also affect its polarity, e.g., in one embodiment, the first barrier layer 118 may include aluminum gallium nitride (AlGaN), the greater the content of aluminum, the greater the polarity of the first barrier layer 118 will be. The stronger the piezoelectric field generated between the first channel layer 116 and the first barrier layer 118, and the greater the electron concentration of the two-dimensional electron gas will be.

In some embodiments, the first channel layer 116 and the first barrier layer 118 may be formed by chemical vapor deposition (CVD), metal organic chemical vapor deposition (MOCVD), molecular beam epitaxy (MBE), physical vapor deposition (PVD), atomic layer deposition (ALD), or other suitable processes. In some embodiments, the first channel layer 116 may include a group III nitride semiconductor material, and the first barrier layer 118 may include a group III nitride semiconductor material with a different composition than the first channel layer 116. In one embodiment, the first channel layer 116 may include intrinsic gallium nitride (i-GaN) (i.e., gallium nitride without doping impurities), and the thickness of the first channel layer 116 may range from about 250 nm to about 350 nm. In other embodiments, without affecting the electron concentration of the two-dimensional electron gas (2DEG), the first channel layer 116 may also be made of i-GaN with a small percentage of other group III elements, such as adding aluminum (Al) or indium (In) as the material of the first channel layer 116. In one embodiment, the first barrier layer 118 may include aluminum gallium nitride (AlGaN), and the thickness of the first barrier layer 118 may range from about 5 nm to about 10 nm. If the thickness of the first barrier layer 118 is too small, the polarization formation of the two-dimensional electron gas (2DEG) may not be effectively enhanced, and if the thickness of the first barrier layer 118 is too large, the electric field may be too concentrated beneath the edge of the gate electrode of the semiconductor device. In one embodiment, the atomic percentage of Al (Al concentration) in the group III elements of the first barrier layer 118 is no greater than 50%, and the atomic percentage of Al (Al concentration) in the group III elements of the first barrier layer 118 is no less than 20%.

Continuing referring to FIG. 1, in one embodiment, the semiconductor structure 100 has a second channel to increase the current density of the device. In one embodiment, the semiconductor structure 100 further includes a second channel layer 126, an intermediate layer 110, and a second barrier layer 128C. The second channel layer 126 is formed on the first barrier layer 118, the second barrier layer 128C is formed over the second channel layer 126, and the intermediate layer 110 is formed between the second channel layer 126 and the second barrier layer 128C. Similar to the first channel layer 116 and the first barrier layer 118, because the second channel layer 126 has a work function difference with the intermediate layer 110, the second channel layer 126 has a second potential well 126W adjacent to an interface (i.e., heterojunction) between the second channel layer 126 and the intermediate layer 110, and the second potential well 126W has two-dimensional electron gas (2DEG). In one embodiment, the energy gap of the intermediate layer 110 is greater than the energy gap of the first barrier layer 118 and greater than the energy gap of the second barrier layer 128C. In one embodiment, the energy gap of the first barrier layer 118 is no less than the energy gap of the second barrier layer 128C, and is less than the energy gap of the intermediate layer 110. The energy gap described above refers to the energy difference between the valence band and the conduction band. In one embodiment, the energy gap of the first barrier layer 118 is, at most, 0.25 eV greater than the energy gap of the second barrier layer 128C, for example, the energy gap of the first barrier layer 118 is 0.15 eV greater, or 0.05 eV greater, than the energy gap of the second barrier layer 128C.

In some embodiments, the second channel layer 126, the intermediate layer 110, and the second barrier layer 128C may be formed by chemical vapor deposition (CVD), metal organic chemical vapor deposition (MOCVD), molecular beam epitaxy (MBE), physical vapor deposition (PVD), atomic layer deposition (ALD), or other suitable processes. In some embodiments, the second channel layer 126 may include a group III nitride semiconductor material, the intermediate layer 110 may include a group III nitride semiconductor material with a different composition than the second channel layer 126, and the second barrier layer 128C may include a group III nitride semiconductor material with a different composition than the second channel layer 126 and the intermediate layer 110. In one embodiment, the second channel layer 126 is similar to the first channel layer 116, the second channel layer 126 may include intrinsic gallium nitride (i-GaN), and the thickness of the second channel layer 126 may range from about 5 nm to about 30 nm. In one embodiment, the intermediate layer 110 may include aluminum nitride (AlN), and the thickness of the intermediate layer 110 may range from about 0.5 nm to about 2 nm. In one embodiment, similar to the first barrier layer 118, the second barrier layer 128C may include aluminum gallium nitride (AlGaN), but the difference is that the Al concentration of the first barrier layer 118 is no less than the Al concentration of the second barrier layer 128C, and the thickness of the second barrier layer 128C may be greater than the thickness of the first barrier layer 118. In one embodiment, the thickness of the second barrier layer 128C may be greater than the thickness of the intermediate layer 110. In one embodiment, the thickness of the second barrier layer 128C may range from about 6 nm to about 30 nm. In one embodiment, the Al concentration of the intermediate layer 110 is greater than the Al concentration of the first barrier layer 118 and greater than the Al concentration of the second barrier layer 128C.

Continuing referring to FIG. 1, in one embodiment, the semiconductor structure 100 further includes source/drain electrodes 150, a gate electrode 160, and a dielectric layer 170. The source/drain electrodes 150 and the gate electrode 160 are formed on the second barrier layer 128C. The source/drain electrodes 150 are formed on opposing sides of the gate electrode 160, and the dielectric layer 170 separates the source/drain electrodes 150 and the gate electrode 160 from each other. In some embodiments, the source/drain electrodes 150 and the gate electrode 160 may be formed by chemical vapor deposition (CVD), physical vapor deposition (PVD), or other suitable methods. In some embodiments, the dielectric layer 170 may be formed by chemical vapor deposition, spin-on coating, atomic layer deposition (ALD), high-density plasma chemical vapor deposition (HDPCVD), or other suitable methods. In some embodiments, the gate electrode 160 may include polysilicon, aluminum, nickel, gold, copper, titanium, tantalum, tungsten, cobalt, molybdenum, tantalum nitride, nickel silicide, cobalt silicide, titanium nitride, tungsten nitride, TiAl, TiAlN, TaCN, TaC, TaSiN, metal alloy, or other suitable materials. The source/drain electrodes 150 may include titanium, aluminum, or other suitable materials. The dielectric layer 170 may include silicon oxide, silicon nitride, or other suitable materials.

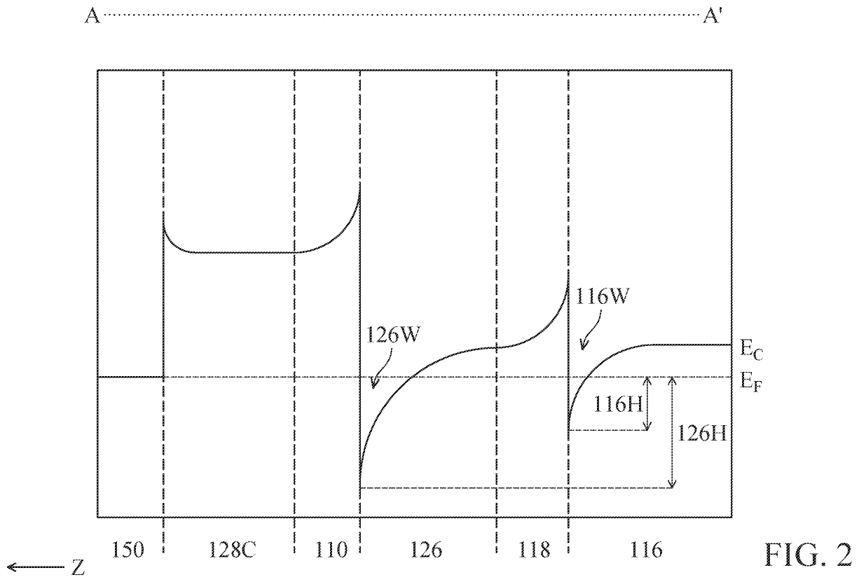

FIG. 2 illustrates an energy band diagram of the semiconductor structure 100 along the line A-A′ of FIG. 1 according to one embodiment of the present disclosure. In FIG. 2, the Fermi level is labeled as E_{F}, and the edge of the conduction band is labeled as E_{C}. In one embodiment, multiple heterojunctions are formed by stacking multiple group III nitride semiconductor layers (e.g., the first channel layer 116, the first barrier layer 118, the second channel layer 126, and the intermediate layer 110), thereby causing multiple bends in the energy band. A potential well is formed deep in the bend of the conduction band. For example, the first potential well 116W is formed in the first channel layer 116 adjacent to the interface between the first channel layer 116 and the first barrier layer 118. Further, the second potential well 126W is formed in the second channel layer 126 adjacent to the interface between the second channel layer 126 and the intermediate layer 110. The first potential well 116W and the second potential well 126W have the two-dimensional electron gas (2DEG). The high energy band of the intermediate layer 110 helps to operate the device in the OFF state, effectively avoiding the generation of leakage currents. In some embodiments, the depth of the potential well may be controlled by varying the work function of the group III nitride semiconductor materials of the first barrier layer 118 and the intermediate layer 110 by changing the aluminum concentration. In some embodiments, the depth 126H of the second potential well 126W is greater than the depth 116H of the first potential well 116W, that is, the electron concentration of the two-dimensional electron gas of the second potential well 126W is greater than the electron concentration of the two-dimensional electron gas of the first potential well 116W. Since the energy band of the intermediate layer 110 is greater than the energy band of the second barrier layer 128C, in one embodiment, the metal of the source/drain electrodes 150 forms an ohmic contact with the second barrier layer 128C, indicating that there is no energy band difference at the metal-semiconductor interface. Further, although the energy band of the intermediate layer 110 is greater than the energy band of the second barrier layer 128C, the energy band of the intermediate layer 110 forms a tunneling energy barrier by combining the energy bands of the second barrier layer 128C, the intermediate layer 110, and the first barrier layer 118. In addition, the depths of the second potential well 126W and the first potential well 116W gradually decrease in depth according to their positions in the semiconductor structure 100. That is, even if the gate potential is affected by the series voltage drop, the deep potential wells may still be effectively turned off, facilitating the operation of the device in the OFF state. In some embodiments, the depth 126H of the second potential well 126W is at least 0.5 eV deeper than the depth 116H of the first potential well 116W, such as 0.2 eV deeper than the depth 116H, 0.3 eV deeper than the depth 116H, or 0.4 eV deeper than the depth 116H, etc.

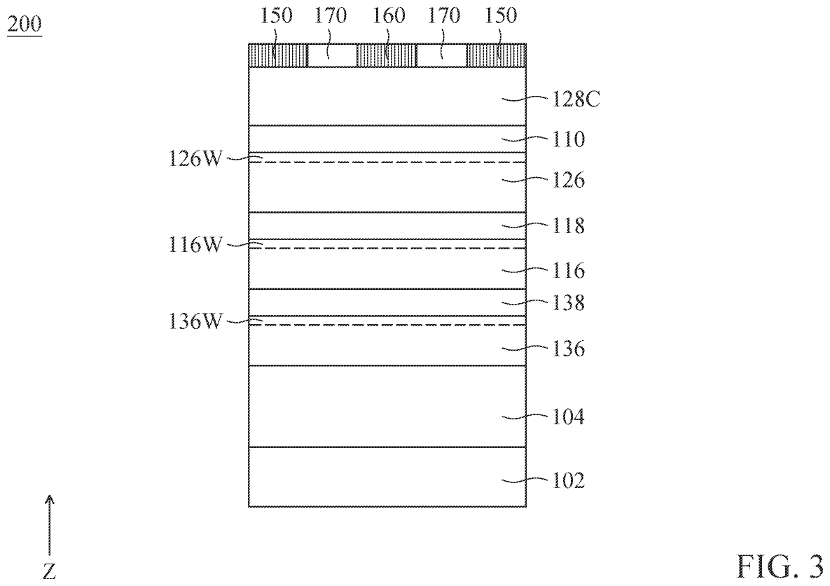

FIG. 3 illustrates a cross-sectional view of the semiconductor structure 200 according to another embodiment of the present disclosure. The described embodiment of FIG. 3 is similar to the described embodiment of FIG. 1, but the difference is that the described embodiment of FIG. 3 further forms a third channel. In the described embodiment of FIG. 3, after the buffer structure 104 is formed, the third channel layer 136 and the third barrier layer 138 are formed first, and then the first channel layer 116 is formed on the third barrier layer 138. Therefore, the third barrier layer 138 is between the first channel layer 116 and the substrate 102, and the third channel layer 136 is between the third barrier layer 138 and the substrate 102. The other components of the semiconductor structure 200 may be described with reference to the semiconductor structure 100 above, and for the sake of simplicity, the description is not repeated herein. Similar to the first channel layer 116 and the first barrier layer 118, because the third channel layer 136 and the third barrier layer 138 have a work function difference, the third channel layer 136 has a third potential well 136W adjacent to an interface (i.e., heterojunction) between the third channel layer 136 and the third barrier layer 138, and the third potential well 136W has two-dimensional electron gas (2DEG). In the described embodiment of FIG. 3, the energy gap of the third barrier layer 138 is no greater than the energy gap of the first barrier layer 118. In the described embodiment of FIG. 3, the energy gap of the first barrier layer 118 is greater than the energy gap of the third barrier layer 138. In the described embodiment of FIG. 3, the energy gap of the first barrier layer 118 is at least 0.2 eV greater than the energy gap of the third barrier layer 138, for example, 0.25 eV greater than the energy gap of the third barrier layer 138, 0.3 eV greater than the energy gap of the third barrier layer 138, 0.4 eV greater than the energy gap of the third barrier layer 138, etc. In the described embodiment of FIG. 3, the energy gap of the third barrier layer 138 is no less than the energy gap of the second barrier layer 128C.

In some embodiments, the third channel layer 136 and the third barrier layer 138 may be formed by chemical vapor deposition (CVD), metal organic chemical vapor deposition (MOCVD), molecular beam epitaxy (MBE), physical vapor deposition (PVD), atomic layer deposition (ALD), or other suitable processes. In some embodiments, the third channel layer 136 may include a group III nitride semiconductor material, and the third barrier layer 138 may include a group III nitride semiconductor material with a different composition than the third channel layer 136. In the described embodiment of FIG. 3, the third channel layer 136 may include intrinsic gallium nitride (i-GaN), and the thickness of the third channel layer 136 may range from about 5 nm to about 10 nm. In the described embodiment of FIG. 3, the third barrier layer 138 may include aluminum gallium nitride (AlGaN), and the thickness of the third barrier layer 138 may range from about 5 nm to about 10 nm. In the described embodiment of FIG. 3, the Al concentration of the first barrier layer 118 is greater than the Al concentration of the third barrier layer 138, wherein the atomic percentage of Al (Al concentration) in the group III elements of the first barrier layer 118 is no greater than 50%, and the atomic percentage of Al (Al concentration) in the group III elements of the first barrier layer 118 is no less than 20%. Therefore, in the energy band diagram (not shown) of the described embodiment of FIG. 3, the depth of the third potential well 136W is less than the depth 116H of the first potential well 116W. In the described embodiment of FIG. 3, the Al concentration of the third barrier layer 138 is no less than the Al concentration of the second barrier layer 128C.

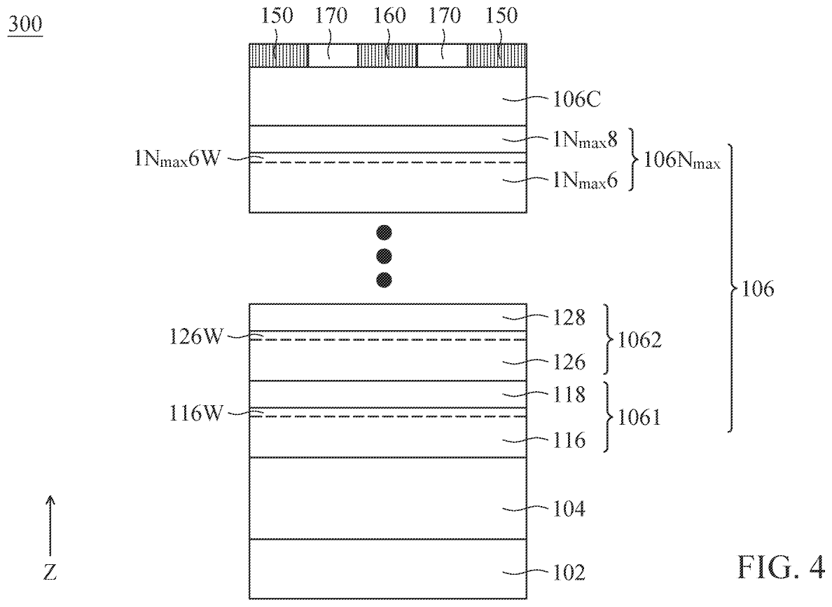

FIG. 4 illustrates a cross-sectional view of the semiconductor structure 300 according to the other embodiment of the present disclosure. The described embodiment of FIG. 4 is similar to the described embodiment of FIG. 1, but the difference is that the described embodiment of FIG. 4 has Nₘₐₓ channels. In the described embodiment of FIG. 4, after the buffer structure 104 is formed, the channel structure 106 is then formed on the buffer structure 104. Forming the channel structure 106 includes sequentially stacking and forming the first channel structure 1061 and the second channel structure 1062 along the first direction (e.g., the coordinate axis Z) until the Nₘₐₓ channel structure 106Nₘₐₓ is formed. The first channel structure 1061 includes a first channel layer 116 and a first barrier layer 118 formed on the first channel layer 116. Similar to the described embodiment of FIG. 1, since the first channel layer 116 and the first barrier layer 118 have a work function difference, the first channel layer 116 has a first potential well 116W adjacent to an interface (i.e., heterojunction) between the first channel layer 116 and the first barrier layer 118, and the first potential well 116W has two-dimensional electron gas (2DEG). In the described embodiment of FIG. 4, the first channel layer 116 and the first barrier layer 118 respectively include group III nitride semiconductor materials with different compositions. The second channel structure 1062 to the Nₘₐₓ channel structure 106Nₘₐₓ are similar to the first channel structure 1061, and all include a channel layer (e.g., channel layer 126/136 . . . /1Nₘₐₓ6) and a barrier layer (e.g., barrier layer 128/138 . . . /1Nₘₐₓ8). In the described embodiment of FIG. 4, the energy gap of the n^{th} (n is a natural number) barrier layer 1Nₙ8 in the first direction (e.g., the coordinate axis Z) is no greater than the energy gap of the n+1^{th} barrier layer 1Nₙ₊₁8. Furthermore, the energy gap of the topmost barrier layer 1Nₘₐₓ8 is greater than the energy gap of any other barrier layer (e.g., barrier layer 118/128 . . . /1Nₘₐₓ₋₁8). After the channel structure 106 is formed, a contact layer 106C may be formed on the channel structure 106, that is, formed on the topmost barrier layer 1Nₘₐₓ8, followed by the formation of the source/drain electrodes 150, the gate electrode 160, and the dielectric layer 170 on the contact layer 106C, similar to the source/drain electrodes 150, the gate electrode 160, and the dielectric layer 170 described in FIG. 1. In the described embodiment of FIG. 4, the contact layer 106C may include a group III nitride semiconductor material, and the energy gap of the contact layer 106C is no greater than the energy gap of any of the barrier layers described above (e.g., barrier layer 118/128 . . . /1Nₘₐₓ₋₁8).

In the energy band diagram (not shown) of the described embodiment of FIG. 4, the depth of the n^{th} potential well 1Nₙ6W along the first direction (for example, the coordinate axis Z) is no greater than the depth of the n+1^{th} potential well 1Nₙ₊₁6W. Further, the depth of the topmost potential well 1Nₘₐₓ6W is greater than the depth of any other potential well (e.g., potential well 116W/126W . . . /1Nₘₐₓ₋₁6W). In the described embodiment of FIG. 4, the energy gap of the topmost barrier layer 1Nₘₐₓ8 is at least 0.2 eV greater than the energy gap of any other barrier layer (e.g., barrier layer 118/128 . . . /1Nₘₐₓ₋₁8), such as 0.25 eV greater, 0.3 eV greater, or 0.4 eV greater, etc. In the described embodiment of FIG. 4, the energy gap of the n+1^{th} barrier layer 1Nₙ₊₁8 is at least 0.2 eV greater than the energy gap of the n^{th} barrier layer 1Nₙ8. In other embodiments, in the other barrier layers described above (e.g., barrier layer 118/128 . . . /1Nₘₐₓ₋₁8), the energy gap of the n+1^{th} barrier layer 1Nₙ₊₁8 is equal to the energy gap of the n^{th} barrier layer 1Nₙ8. In the described embodiment of FIG. 4, the atomic percentage of Al (Al concentration) in the group III elements of the topmost barrier layer 1Nₘₐₓ8 is at least 20% greater than the atomic percentage of Al in the group III elements of the other barrier layers described above (e.g., barrier layer 118/128 . . . /1Nₘₐₓ₋₁8). In the described embodiment of FIG. 4, the atomic percentage of Al (Al concentration) in the group III elements of the n+1^{th} barrier layer 1Nₙ₊₁8 is at least 20% greater than the atomic percentage of Al in the group III elements of the n^{th} barrier layer 1Nₙ₊₁8, that is, the semiconductor structure 300 has a variable gradient of Al concentration. In other embodiments, in the other barrier layers described above (e.g., barrier layer 118/128 . . . /1Nₘₐₓ₋₁8), the Al concentration of the n+1^{th} barrier layer 1Nₙ₊₁8 is equal to the Al concentration of the n^{th} barrier layer 1Nₙ8. In the described embodiment of FIG. 4, the thickness of the channel layer (e.g., channel layer 116/126 . . . /1Nₘₐₓ₋₁6) may range from about 5 nm to about 20 nm. In the described embodiment of FIG. 4, the thickness of any other barrier layer (e.g., barrier layer 118/128 . . . /1Nₘₐₓ₋₁8) may range from about 5 nm to about 10 nm. In the described embodiment of FIG. 4, the thickness of the topmost barrier layer 1Nₘₐₓ8 may range from about 0.5 nm to about 2 nm.

In summary, the embodiments of the present disclosure provide a semiconductor structure with multiple channel counts. The difference in the work function is caused by the variation of Al concentration in the barrier layer, thereby controlling the energy band profile of the device. In addition, forming the desired multiple potential wells and obtaining high current density while improving the leakage current problem of the device in the OFF state. Thus, the various embodiments described herein offer several advantages over the existing art. It will be understood that not all advantages have been necessarily discussed herein, no particular advantage is required for all embodiments, and other embodiments may offer different advantages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first channel layer comprising a group III nitride semiconductor material;
a first barrier layer on the first channel layer comprising a group III nitride semiconductor material, wherein the first channel layer has a first potential well adjacent to an interface between the first channel layer and the first barrier layer, wherein the first potential well has a two-dimensional electron gas (2DEG);
a second channel layer on the first barrier layer comprising a group III nitride semiconductor material;
a second barrier layer on the second channel layer comprising a group III nitride semiconductor material; and
an intermediate layer between the second channel layer and the second barrier layer comprising a group III nitride semiconductor material, wherein the second channel layer has a second potential well adjacent to an interface between the second channel layer and the intermediate layer, wherein the second potential well has a two-dimensional electron gas,
wherein an energy gap of the intermediate layer is greater than an energy gap of the first barrier layer and an energy gap of the second barrier layer,
wherein the energy gap of the first barrier layer is no less than the energy gap of the second barrier layer, and lower than the energy gap of the intermediate layer, and
wherein a depth of the second potential well is greater than a depth of the first potential well in an energy band diagram.

2. The semiconductor structure as claimed in claim 1, wherein the energy gap of the first barrier layer is, at most, 0.25 eV greater than the energy gap of the second barrier layer.

3. The semiconductor structure as claimed in claim 1, wherein the depth of the second potential well is 0.5 eV deeper than the depth of the first potential well.

4. The semiconductor structure as claimed in claim 1, wherein an Al concentration of the intermediate layer is greater than an Al concentration of the first barrier layer and an Al concentration of the second barrier layer.

5. The semiconductor structure as claimed in claim 1, wherein an Al concentration of the first barrier layer is no less than an Al concentration of the second barrier layer.

6. The semiconductor structure as claimed in claim 1, wherein an atomic percentage of Al in a group III element of the first barrier layer is no greater than 50%, and the atomic percentage of Al in the group III element of the first barrier layer is no less than 20%.

7. The semiconductor structure as claimed in claim 1, wherein a thickness of the second channel layer is from 5 nm to 30 nm, a thickness of the first barrier layer is from 5 nm to 10 nm, a thickness of the intermediate layer is from 0.5 nm to 2 nm, and a thickness of the first channel layer is from 250 nm to 350 nm.

8. The semiconductor structure as claimed in claim 1, further comprising:
a substrate under the first channel layer;
a third barrier layer between the first channel layer and the substrate; and
a third channel layer between the third barrier layer and the substrate,
wherein the third channel layer has a third potential well adjacent to an interface between the third channel layer and the third barrier layer, wherein the third potential well has a two-dimensional electron gas.

9. The semiconductor structure as claimed in claim 8, wherein a depth of the third potential well is smaller than the depth of the first potential well in the energy band diagram.

10. The semiconductor structure as claimed in claim 8, wherein the energy gap of the first barrier layer is greater than an energy gap of the third barrier layer.

11. The semiconductor structure as claimed in claim 8, wherein the energy gap of the first barrier layer is 0.2 eV greater than an energy gap of the third barrier layer.

12. The semiconductor structure as claimed in claim 8, wherein an energy gap of the third barrier layer is no less than the energy gap of the second barrier layer.

13. The semiconductor structure as claimed in claim 8, wherein an Al concentration of the first barrier layer is greater than an Al concentration of the third barrier layer, an atomic percentage of Al in a group III element of the first barrier layer is no greater than 50%, and the atomic percentage of Al in the group III element of the first barrier layer is no less than 20%.

14. The semiconductor structure as claimed in claim 8, wherein an Al concentration of the third barrier layer is no less than an Al concentration of the second barrier layer.

15. The semiconductor structure as claimed in claim 8, wherein a thickness of the third barrier layer is from 5 nm to 10 nm.

16. A semiconductor structure, comprising:
a plurality of channel structures stacked sequentially along a first direction, wherein the plurality of channel structures comprises a plurality of channel layers and a plurality of barrier layers alternatively stacked along the first direction, each of the channel structures comprises:
one of the channel layers comprising a group III nitride semiconductor material; and
one of the barrier layers on the one of the channel layers, comprising a group III nitride semiconductor material, wherein the one of the channel layers has a potential well adjacent to an interface between the one of the channel layers and the one of the barrier layers, wherein the potential well has a two-dimensional electron gas,
wherein an energy gap of an n^{th} barrier layer of the barrier layers is no greater than an energy gap of an n+1^{th} barrier layer of the barrier layers along the first direction, and an energy gap of a topmost barrier layer of the barrier layers is greater than an energy gap of any other barrier layer, wherein n is a natural number, and
wherein a depth of an n^{th} potential well of an n^{th} channel layer of the channel layers is no greater than a depth of the n+1^{th} potential well of an n+1^{th} channel layer of the channel layers along the first direction, and a depth of a topmost potential well of a topmost channel layer of the channel layers is greater than a depth of any other potential well in an energy band diagram; and
a contact layer over the channel structures, wherein the contact layer comprises a group III nitride semiconductor material, and an energy gap of the contact layer is no greater than an energy gap of any other barrier layer.

17. The semiconductor structure as claimed in claim 16, wherein the energy gap of the topmost barrier layer is at least 0.2 eV greater than the energy gap of any other barrier layer or wherein the energy gap of the n+1^{th} barrier layer is at least 0.2 eV greater than the energy gap of the n^{th} barrier layer.

18. The semiconductor structure as claimed in claim 16, wherein the energy gap of the topmost barrier layer is at least 0.2 eV greater than the energy gap of any other barrier layer, and the energy gap of the n+1^{th} barrier layer is equal to the energy gap of the n^{th} barrier layer in the other barrier layers.

19. The semiconductor structure as claimed in claim 16, wherein an atomic percentage of Al in a group III element of the topmost barrier layer is 20% greater than an atomic percentage of Al in the group III element of the other barrier layers, or an atomic percentage of Al in the group III element of the n+1^{th} barrier layer is at least 20% greater than an atomic percentage of Al in the group III element of the n^{th} barrier layers.

20. The semiconductor structure as claimed in claim 16, wherein an atomic percentage of Al in a group III element of the topmost barrier layer is 20% greater than an atomic percentage of Al in the group III element of the other barrier layers, and an Al concentration of the n+1^{th} barrier layer is equal to an Al concentration of the n^{th} barrier layer in the other barrier layers.
